(19) United States
(12) Patent Application Publication
(10) Pub. No.: US 2010/0007363 A1
(43) Pub. Date: Jan. 14, 2010

(54) SYSTEM AND METHOD FOR DETERMINING IN-LINE INTERFACIAL OXIDE CONTACT RESISTANCE

(75) Inventors: Miles DUDMAN, Mountain View, CA (US); Andrew LE, San Jose, CA (US); Daniel ANDERSON, Fremont, CA (US)

Correspondence Address: SAWYER LAW GROUP PC, 2465 E. Bayshore Road, Suite No. 406, PALO ALTO, CA, 94303, US

(73) Assignee: Micrel, Inc., San Jose, CA (US)

(21) Appl. No.: 11/949,245

(22) Filed: Dec. 3, 2007

(51) Int. Cl. G01R 27/08

(52) U.S. Cl. 324/715

(57) ABSTRACT

The present invention relates generally to semiconductor wafer fabrication and more particularly but not exclusively to advanced process control methodologies for measuring in-line contact resistance in relation to oxide formations. The present invention, in one or more implementations, include an in-line method of determining contact resistance across a semiconductor wafer and determining the contact resistance value and the number of monolayers of the wafer.

### FIELD OF THE INVENTION

The present invention relates generally to semiconductor wafer fabrication and more particularly but not exclusively to advanced process control methodologies for measuring in-line contact resistance in relation to oxide formations.

### BACKGROUND OF THE INVENTION

Demand for semiconductors, wafers, integrated circuits and semiconductor devices (i.e., collectively “semiconductors”) continues to rapidly increase. With the continued market demand, there remain market pressures to increase the number of wafers that can be processed, reduce the geometries of finished wafers and their associated chip footprints, and increase component counts in the reduced geometries. Being able to sustain and meet the market demands with a reliable and consistent offering is a challenge however, in part because wafer manufacture is an environment that is both process sensitive and equipment intensive. Similarly, since wafer fabrication is an expense process, determining as early as possible potential problems or limitations of a process are desired.

The fabrication of wafers (i.e., fabrication, fab, or fab environment) requires advanced processing equipment, unique toolings and extensive research efforts. Process tools (i.e., toolings) in these environments may often run in parallel or have multiple components to produce similar products (i.e., yields or outputs). Yet these same process tools, even when of the same manufacturer or source, may have unique variances in their individual performances which may create substantial differences in the quality and performance of fabricated wafers as well as the products comprising the wafers.

FIG. 1 depicts an example of a typical wafer 100 produced by a process tool, such as horizontal furnace, in an established process. In FIG. 1, the wafer 100 has elements which may vary with respect to the type of process tooling and fab process undertaken in its manufacture, including a substrate 120 and a memory cell area 130. A memory cell often includes two or more field oxide areas (i.e., isolation regions) 110 which are often grown areas of oxide formed by a local oxidation of silicon (LOCOS) process.

The LOCOS process is in effect an isolation scheme commonly used in metal oxide semiconductors (MOS) and complementary MOS (CMOS) technology in which a thick pad of thermally grown SiO2 separates adjacent devices such as P-channel MOS and N-channel MOS transistors. Local oxidation is often accomplished by using silicon nitride to prevent oxidation of silicon in predetermined areas, and silicon is typically implanted between a silicon nitride region to form channel stops.

From FIG. 1, the memory cell 130 is formed above an active area 140 of the substrate 120 and is situated typically between the adjacent field isolation regions 110. The memory cell 130 typically comprises a gate insulation layer 135 (i.e., tunnel oxide layer), a floating gate electrode 145 (often of polysilicon), a composite inter-poly insulation layer 150, and a control gate electrode 160 (often of polysilicon). In many implementations of the example of FIG. 1, the insulation layer 150 is also known as an oxide-nitride-oxide (ONO) layer as it is often comprised of a layer of silicon dioxide 151, a layer of silicon nitride 152 and a layer of silicon dioxide 153, though other variations are also known.

From FIG. 1, the thickness and dielectric constants of the floating gate electrode 135 and the layers of each of the ONO layer (i.e., 151, 152 and 153) may affect the overall performance of the memory cell and the associated integrated or electronic circuitry, depending on their thickness and formation details. Similarly there are also other characteristics of the memory cell related to physical structures, thickness, conductivity, uniformity, capacitance, band voltage, resistance, and growth impacts due to temperature and/or pressure during the deposition process, which may affect performance which directly results from a process tool's operation on the wafer (i.e., collectively “performance variables,” “performance variances” or “performance characteristics”).

In a traditional furnace or furnace bank, there may exist more than one furnace tube in which a predetermined number of furnace tubes perform a similar process. FIG. 2 depicts a typical eight-tube furnace bank arrangement 190.

By example, the furnace bank of FIG. 2 is a process tool having two four-furnace banks at 191a and 191b, totaling eight similar separate tubes (i.e., furnace tubes) (191a, 191b, 191c, 191d, 191e, 191f, 191g, and 191h), each arranged to perform a furnace-based activity on a wafer set in the fab process. In a typical arrangement 190, each tube is arranged to receive a set of silicon wafers (192a, 192b, 192c, 192d, 192e, 192f, 192g, and 192h) which are typically received by the respective tube of the arrangement 190. In FIG. 2, by example, wafer set 192h is about to be received into the proper bay area of furnace tube 191h, while all other wafer sets have been properly positioned in their respective tube bay. At 193a, 193b, 193c, 193d, 193e, 193f, 193g, and 193h are controllers each of which controls its respective furnace tube along 194a or 194b. Both pressure and heat source are integral features of a typical furnace (not shown). Once the wafers are inserted into the their respective tubes, the wafers are acted upon in accordance with the designated process, and thereafter removed.

FIG. 3 depicts a typical horizontal diffusion furnace scavenger system 300 for a particular process. In FIG. 3, by example, the horizontal furnace 300 is designed to perform Diffusion/Atmospheric and Low Pressure Chemical Vapor Deposition (LPCVD) processing on predetermined wafers of a particular range of sizes. The Example configuration of FIG. 3 is referred to as a right-handed system, as determined in relation to the position of the furnace with regard to an operator. The horizontal furnace includes a load station at 310 in which wafers are loaded for travel into the furnace portion 320 of the horizontal furnace for processing. A gas cabinet provides associated gases for furnace processing at 330. A power system provides power and control logic to the system at 340. Operatively, once the wafers are fully processed, the wafers are removed from the furnace and returned to the load station.

In one deposition example, during the fabrication operation, a layer of insulating material and a layer of polycrystalline silicon are typically provided on a surface of a silicon wafer. In many operations, the layer of polycrystalline silicon includes a tunnel window, and the layer of insulating material is then removed from the surface of the silicon wafer within the window and below an edge of the layer of polycrystalline silicon adjacent to the window. Thereafter, the silicon is selectively deposited on the monocrystalline and polycrystalline silicon exposed in and adjacent to the window via various vapor deposition processes at various pressures or temperatures, in relation to a particular process. At a reduced pressure, such an operation may provide a reasonably smooth deposition layer of silicon having a generally homogeneous thickness.

Alternatively, a nitride layer or an oxynitride layer can be deposited onto a substrate utilizing known deposition methods such as thermal chemical vapor deposition (TCVD), that is carried out in the absence of a plasma, plasma-enhanced chemical vapor deposition (PECVD), or atomic layer deposition (ALD). Similarly, other types of deposition methods are envisioned by the present invention including but not limited to depositions involving metals (i.e., metallization) and barrier metals. Collectively, these methods of deposition are generally referenced and included herein as “deposition methods.”

However these deposition methods are directly affected by the presence of oxide on a Si wafer surface.

The presence of oxides, also known as native oxides, on a Si wafer surface is recognized as directly affecting the performance of a wafer, in part as the success or failure of the deposition step is impacted. In certain situations, the oxide present may affect the quality and deposition processes of polysilicon and dielectric thin films. In other situations, by example, the oxide present may cause incubation before film growth during low-pressure CVD. It will also be appreciated by those in skilled in the art that the presence of the oxide may also present further ramifications affecting the wafer, fabrication of the wafer, and performance of the wafer. However, attempts to suppress the native oxide growth during the surface cleaning and precisely control the interface (i.e., interfacial oxide) have not alleviated these concerns nor the formation of oxide.

For instance, in a fabrication environment, there may exist multiple deposition locations where a polysilicon, such as but not limited to polycrystalline silicon, is to be deposited on a silicon substrate surface of a wafer. Prior to the deposition process, the wafers are typically cleaned within the facility by a cleaning step that may include treating the wafer surface with dilute hydrofluoric acid, rinsing the wafer with ultra pure water, and drying the wafer. Often, there may be multiple cleaning process locations and depositing process locations within the facility, each process having identically calibrated equipment and each set of equipment for each process following a common cleaning or deposition regiment. However, even under these circumstances, following a deposition process, future examination of produced wafers from these processes may show that the polysilicon deposition results of one wafer versus another are sufficiently different. For instance grain sizes, grain distributions, and unwanted contamination at one location versus another may be present wafers having sufficient differences resulting in the success or failure of one produced set of wafers over another. In these situations, the additional or unexpected formation of oxide at one location versus the other location results in insufficient polysilicon deposition thereby producing wafers from which are substandard.

Unfortunately, the determination of a fabricated wafer having poor performance characteristics is typically determinable only at an end-of-line point, post-fabrication, or well after the fabrication is fully completed.

For example, following a wafer fabrication process, a wafer is typically situated for inspection and testing. The wait for an inspection and testing may be of a period in excess of two weeks after fabrication. Accordingly, an interfacial oxide layer formed in the wafer may be determined to be of an inconsistent or inaccurate thickness at such time, thereby rendering the produced wafer, and possibly the related batch of produced wafers, unusable well-after the wafer was produced.

Further, for instance, a logic bipolar transistor (LPT) is an example of a semiconductor device that has improved performance provided it has a low polysilicon to silicon substrate contact resistance (i.e., also used herein as contact resistivity). In other semiconductor devices, the contact resistance is also a determinate in the performance of the device. However, using traditional approaches, the contact resistance cannot be determined until well-after the fabrication production is completed resulting in a situation where a produced wafer and its production group may ultimately be discarded weeks after being completed and having taken up inventory space and planning.

FIG. 4 shows a representative cross-sectional view of an interfacial oxide layer resulting from an oxidation process in accordance with one or more known cleaning and deposition methods. It is readily recognized that in a thermal oxidation process, a portion of the silicon substrate is consumed and the resulting silicon oxide expands upward during the growth cycle, with regard to the original silicon/air position. The resulting silicon/silicon oxide interface (i.e., interfacial oxide layer), moves into the silicon during the oxidation process. The interfacial oxide layer may be comprised of less than one monolayer or more than one monolayer of polysilicon, depending on the fabrication process.

From FIG. 4, a wafer 400 is comprised of a substrate 410, an interfacial oxide layer 420 and a deposition layer 430, typically of polysilicon, achieved through a deposition method. It will be appreciated by those skilled in the art that the Figure is not intended to represent uniform deposition results and does not demonstrate a deposition layer necessarily representative of that attainable with an interfacial oxide layer.

Typically a thickness of the interfacial oxide layer 420 may range from a few angstroms to over 20 angstroms, and the polysilicon deposition layer may be approximately one or more microns, depending on a process. However, the interfacial oxide may be not be uniformly consistent, may be inconsistent in thickness due to the process or anomalies encountered in a process, and the oxide grown during the cleaning process in a deposition method may also be unexpectedly affected. As the oxide may be inconsistent or may have grown at varied rates, the contact resistance of a produced wafer, which is directly proportionate to the presence of oxide at the end of the process (i.e., “end of the line” amount), may also be affected.

Accordingly, it is desired to determine the layers of the interfacial oxide and hence the contact resistance as soon as is possible following production operations with minimal interruption to the process schedule. The present invention, in accordance with its various implementations herein, addresses such needs.

### SUMMARY OF THE INVENTION

In one implementation of the present invention, a method of determining contact resistance across and a number of interfacial oxide monolayers of a semiconductor wafer, comprising: measuring a voltage and a current across a wafer using a probe assembly, relating the measured voltage and current to a predetermined contact resistance association, and, determining the contact resistance value and the number of monolayers of the wafer, is set forth.

In another implementation, the present invention is a method of in-line resistance testing a wafer during fabrication to determine contact resistance and identify an interfacial oxide composition, comprising: measuring a voltage and a current across a wafer using an in-line multi-tipped probe being conductive with a surface of the wafer, determining (i) a contact resistance in relation to the measured voltage and current and (ii) a number of monolayers for the interfacial oxide composition in relation to the determined contact resistance, and, passing or failing the wafer in relation to the determining step.

In a further implementation, the present invention is a computer program product for passing or failing a wafer during fabrication in response to determined contact resistance, comprising, the computer program product comprising a computer-readable storage medium having computer-readable program code portions stored therein, the computer-readable program code portions comprising: a first executable portion having instructions providing a capability of: measuring a voltage and a current across a wafer via instructions to an in-line multi-tipped probe being conductive with a surface of the wafer, determining (i) a contact resistance in relation to the measured voltage and current and (ii) a number of monolayers for the interfacial oxide composition in relation to the determined contact resistance, and, signaling the passing or failing of the wafer in relation to the determining step.

### BRIEF DESCRIPTION OF THE DRAWINGS

FIG. 1 depicts an example of a typical wafer produced by a process tool, such as horizontal furnace, in an established process;

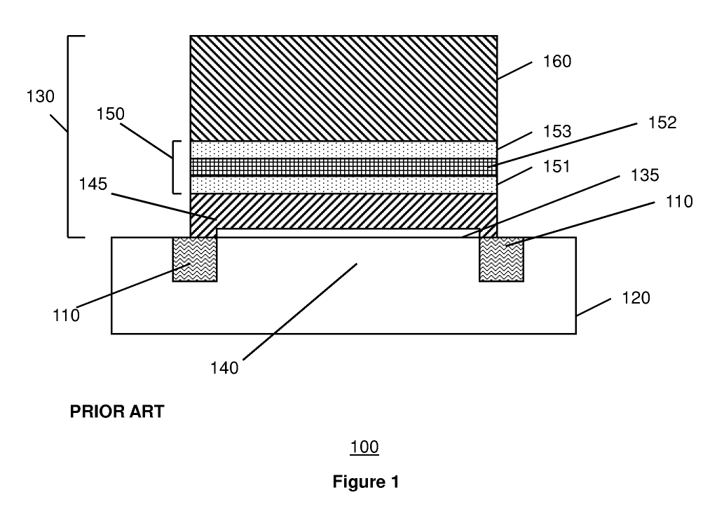

FIG. 2 depicts a typical eight tube furnace bank arrangement;

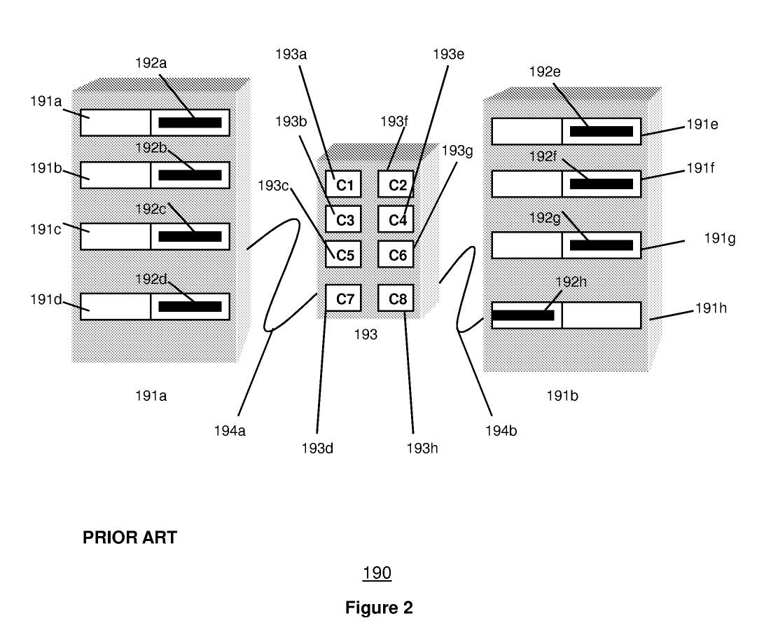

FIG. 3 depicts a typical horizontal diffusion furnace scavenger system for a particular process;

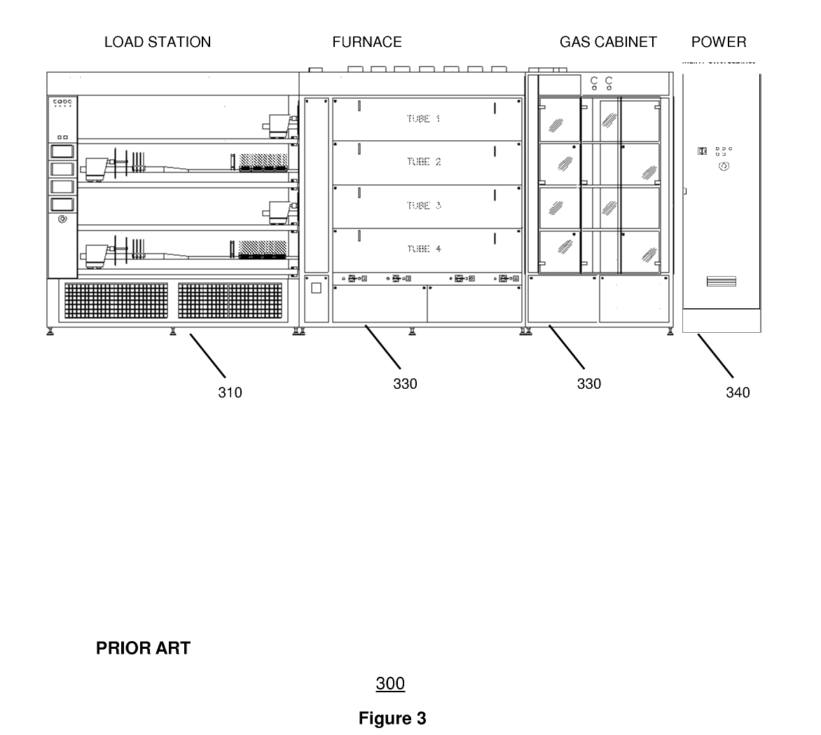

FIG. 4 shows a representative cross-sectional view of an interfacial oxide layer resulting from an process in accordance with one or more known cleaning and deposition methods;

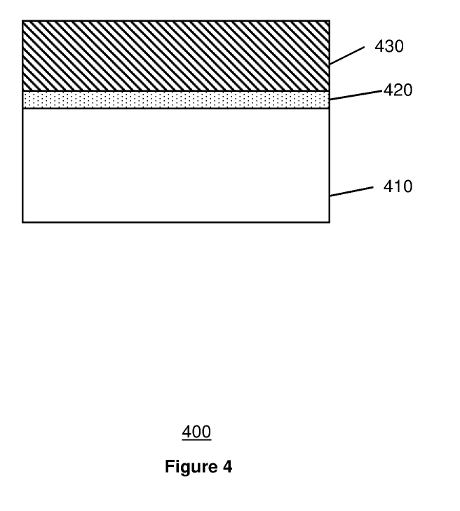

FIG. 5 depicts a 4-point probe for measuring the contact resistance of the interfacial oxide layer of a produced wafer during an in-line test, in accordance with an implementation of the present invention; and,

FIG. 6 depicts a process for determining a pass/fail event using the present invention in one or more implementations.

### DETAILED DESCRIPTION

The present invention relates generally to semiconductor wafer fabrication and more particularly but not exclusively to advanced process control methodologies for measuring in-line contact resistance in relation to oxide formations.

The following description is presented to enable one of ordinary skill in the art to make and use the invention and is provided in the context of a patent application and its requirements. Various modifications to the preferred embodiments and the generic principles and features described herein will be readily apparent to those skilled in the art. Thus, the present invention is not intended to be limited to the embodiments shown, but is to be accorded the widest scope consistent with the principles and features described herein.

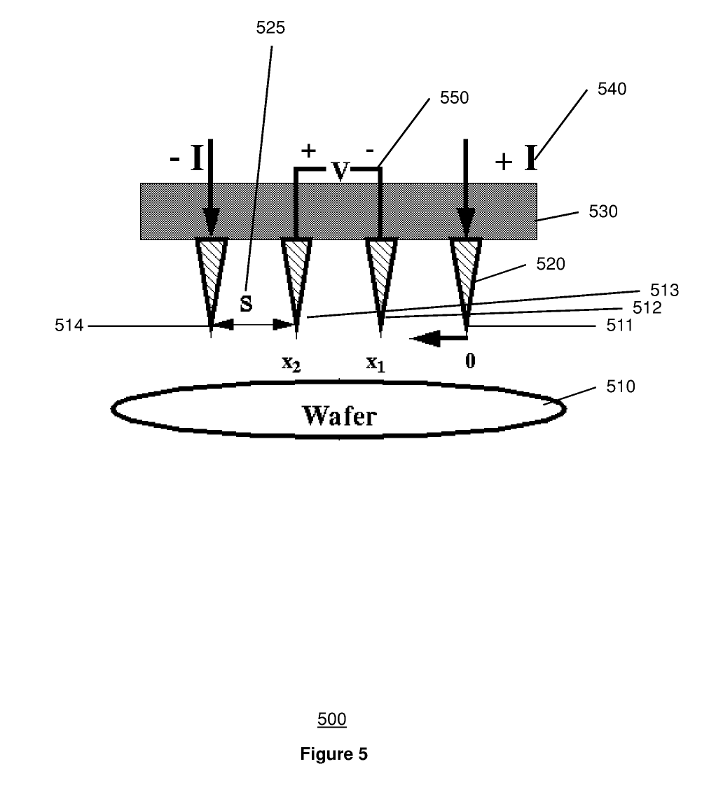

FIG. 5 depicts a 4-point probe 500, for example, for measuring the contact resistance of the interfacial oxide layer of a produced wafer 510 during an in-line test, in an implementation of the present invention. As used herein, the four point probe is an exemplary implementation of a probe device however other variations of a probe are envisioned by the present invention; therefore as used herein the term “probe” is intended to be a four point probe as well as other variations having similar functionality and capability.

The four-point probe 500 having four probes (520) with pressure-contact tips (511, 512, 513 and 514) can be brought into electrical contact with a stationary wafer 510 produced through an in-line test following the deposition process. The probe is capable of measuring a current (I) and voltage (V) information of the substrate and thereby relating the measurements to thickness of oxides and contact resistance of the produced wafer, in accordance with an implementation of the present invention.

The current/voltage tips of the four-point probe may be arranged in a predetermined manner (e.g., in a line, pattern or other configuration) using an adapted probe tip to minimize physical damage to the wafer surface. In one particular example, in an implementation of the present invention, the probe consists of four equally spaced (525) metal tips, each with a finite radius and configured with a dampening device at 530 (i.e., springs) to minimize sample damage during probing. The four metal tips may also be configured with an auto-mechanical stage (optionally 530) which travels up and down during measurements. A high impedance current source is used to supply current through the outer two probes at 540. A voltmeter measures the voltage across the inner two probes at 550 to determine the contact resistance. In a further implementation, the typical probe spacing may approximate a distance of about 1 mm between each probe.

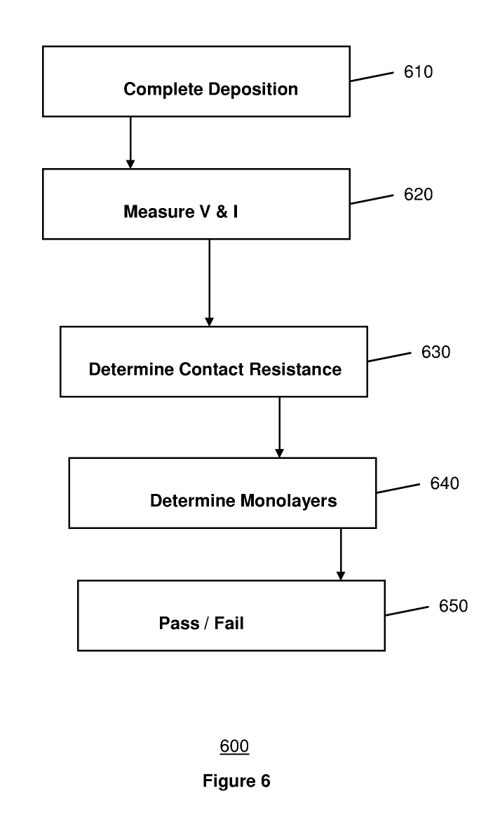

FIG. 6 depicts a process 600 for determining a pass/fail event using the present invention in one or more implementations. After the process has completed its deposition phase 610, the voltage and current across a wafer are measured using a probe at 620. The measured voltage and current of 620 are then related to determine the contact resistance in accordance with V/I at 630. The number of monolayers present in an interfacial oxide may then be determined in relation to the step of 630 by using a look-up or relational association to determine the number of monolayers present, at 640. Depending on the number of monolayers and the desired purpose of the fabricated wafer, a pass or fail determination may be made at 650 prior to completion of the entire fabrication process.

In the present invention, in one or more implementations, the probe is positioned at a point in the fabrication process (i.e., oxidation cycle) which follows precleaning and deposition, such that it is “in-line” with the fabrication process. By example a cleaning process may include a standard wet clean operation having sulfuric acid, hydrofluoric acid and a spin rinse dryer (SRD), though other variations are also envisioned. The probe is capable of measuring the V and I across a wafer at this stage of the fabrication so as to determine whether the polysilicon layer of the wafer is monolithic or polylithic as a result of manufacture. Typically, in one or more implementations of the present invention, a monolayer (i.e., monolithic) of polysilicon is approximately equal to or less than one micron in dimension, whereas a wafer having more than one monolayer or being multilayered will have a thickness is excess of this measurement. Since the contact resistance across the polysilicon is determined in relation to the thickness of the polysilicon layer, measurements by the probe of V/I for a particular wafer may then result in determining the wafer as being of a monolayer or multilayer of polysilicon based upon predetermined V/I values in relation to contact resistivity values. In a preferred embodiment, where the measured V/I by the probe of a wafer is approximately equal to or less than 50 ohm centimeters (Ωcm) then the wafer has less than one single monolayer of polysilicon as an interfacial oxide layer. In a further preferred embodiment, where the measured V/I by the probe of a wafer is approximately greater than 1000 ohm centimeters (Ωcm) then the wafer has two or more monolayers of polysilicon in the interfacial oxide layer.

In operation, the present invention in one or more implementations, is positioned in-line to the fabrication process such that the probe tips are in conductive arrangement with a polysilicon layer of the wafer to be tested. A high impedance current source is used to supply current through the outer two probes tips of the probe, and a voltmeter measures the voltage across the inner two probes tips to determine the sample resistivity of the wafer. The wafer resistivity is determined as V/I for the purposes of the present invention. In relation to the resulting V/I determination, where the measured V/I by the probe of a wafer is approximately equal to or less than 50 ohm centimeters (Ωcm) then it is determined that wafer has less than one single monolayer of polysilicon as an interfacial oxide layer. In a further preferred embodiment, where the measured V/I by the probe of a wafer is determined as being approximately greater than 1000 ohm centimeters (Ωcm) then the wafer is determined as having two or more monolayers of polysilicon in the interfacial oxide layer.

The present invention is further advantageous over traditional methods as no additional modifications or change-outs are required in the functional or operative nature of the fab process to which it impacts. Time savings, costs savings, inventory and scrap savings are also readily anticipated by the present invention in an operational environment. A further advantage is that the present invention does not require the need to “profile” tooling such as furnaces, contradistinctive to the traditional approach.

As used herein it will be understood that the performance of a wafer or memory cell may be impacted by one or more, or any of: film thickness, stress and dopant percentages, oxide thickness, dielectric constants of the floating gate electrode and layers of the ONO layer, physical attributes, footprint, shape, formation details, thickness, conductivity, uniformity, capacitance, band voltage, resistance, and growth impacts dues to temperature and/or pressure during the deposition process, and other characteristics which may affect performance.

As used herein, it is envisioned that the present invention in one or more implementations may be hardware, software, firmware, or combinations thereof, in its composition and operation, and may therefore further comprise software, instructional code, other applications, and be a computer program product.

Various implementations of a wafer process and methods for fabricating the wafer have been described. Nevertheless, one of ordinary skill in the art will readily recognize that various modifications may be made to the implementations, and any variations would be within the spirit and scope of the present invention. For example, the above-described process flow is described with reference to a particular ordering of process actions. However, the ordering of many of the described process actions may be changed without affecting the scope or operation of the invention. Accordingly, many modifications may be made by one of ordinary skill in the art without departing from the spirit and scope of the following claims.

What is claimed is:

1. A method of determining contact resistance across and a number of interfacial oxide monolayers of a semiconductor wafer, comprising:
measuring a voltage and a current across a wafer using a probe assembly,
relating the measured voltage and current to a predetermined contact resistance association, and,
determining the contact resistance value and the number of monolayers of the wafer.

2. The method of claim 1, wherein the predetermined contact resistance association is a relational logic associating a value of (V/I) measurable by the probe to a number of monolayers of polysilicon oxide of the interfacial oxide layer of the wafer.

3. The method of claim 2, wherein the relation logic is a look up table.

4. The method of claim 2, where when a measured the value of (V/I) is approximately less than or equal to 50 ohm cm, the wafer is determined to have less than one monolayer of in the interfacial oxide layer.

5. The method of claim 2, where when a measured the value of (V/I) is greater than approximately 1000 ohm cm, the wafer is determined to more than two monolayers in the interfacial oxide layer.

6. The method of claim 2, where when a measured the value of (V/I) is greater than approximately 50 ohm cm and less than approximately 1000 ohm cm, the wafer is determined to have at least one monolayer in the interfacial oxide layer.

7. The method of claim 2, wherein the step of measuring is performed following a deposition process.

8. The method of claim 2, wherein the step of measuring is performed in-line following precleaning and deposition, during a fabrication process.

9. The method of claim 8, wherein the probe is comprised of at least one probe tip set to determine voltage and one probe tip set to determine current for the measuring step.

10. The method of claim 9, wherein the probe tip sets each comprise at least twp probe tip adapted for use with polysilicon layers of the wafer and arranged at equidistant spacing from one another in relation to a surface of the wafer.

11. The method of claim 10, wherein the wafer is a dielectric for a transistor.

12. The method of claim 10, further comprising a high impedance current source supplying supply current through an outer probe tip set, and a voltmeter measuring voltage across an inner probe tip set for determining contact resistance of the wafer.

13. A method of in-line resistance testing a wafer during fabrication to determine contact resistance and identify an interfacial oxide composition, comprising:
measuring a voltage and a current across a wafer using an in-line multi-tipped probe being conductive with a surface of the wafer,
determining (i) a contact resistance in relation to the measured voltage and current and (ii) a number of monolayers for the interfacial oxide composition in relation to the determined contact resistance, and,
passing or failing the wafer in relation to the determining step.

14. The method of claim 13, wherein the step of determining contact resistance includes calculating a value of (V/I) from information measured the probe.

15. The method of claim 14, wherein the step of determining a number of monolayers for the interfacial oxide composition in relation to the determined contact resistance relation logic is performed using a look up table.

16. The method of claim 15, where when a measured the value of (V/I) is approximately less than or equal to 50 ohm cm, the wafer is determined to have less than one monolayer of in the interfacial oxide layer.

17. The method of claim 16, wherein the wafer is determined to pass.

18. The method of claim 15, where when a measured the value of (V/I) is greater than approximately 1000 ohm cm, the wafer is determined to more than two monolayers in the interfacial oxide layer.

19. The method of claim 18, wherein the wafer is determined to fail.

20. The method of claim 15, where when a measured the value of (V/I) is greater than approximately 50 ohm cm and less than approximately 1000 ohm cm, the wafer is determined to have at least one monolayer in the interfacial oxide layer.

21. The method of claim 15, wherein the step of measuring is performed following a deposition process.

22. The method of claim 21, wherein the step of measuring is performed in-line following precleaning and deposition, during a fabrication process.

23. The method of claim 15, wherein the multi-tipped probe is comprised of at least two probe tips to determine voltage and two other probe tips to determine current for the measuring step.

24. The method of claim 23, wherein each probe tip comprises a probe tip adapted for use with polysilicon layers of the wafer and arranged at equidistant spacing from one another in relation to a surface of the wafer.

25. The method of claim 24, wherein the wafer is for a logic bipolar transistor.

26. The method of claim 24, further comprising a high impedance current source supplying supply current through two of the probe tips, and a voltmeter measuring voltage across two other probe tips for determining contact resistance of the wafer.

27. A computer program product for passing or failing a wafer during fabrication in response to determined contact resistance, comprising, the computer program product comprising a computer-readable storage medium having computer-readable program code portions stored therein, the computer-readable program code portions comprising: a first executable portion having instructions providing a capability of:
measuring a voltage and a current across a wafer via instructions to an in-line multi-tipped probe being conductive with a surface of the wafer,
determining (i) a contact resistance in relation to the measured voltage and current and (ii) a number of monolayers for the interfacial oxide composition in relation to the determined contact resistance, and,
signaling the passing or failing of the wafer in relation to the determining step.

28. The product of claim 27, wherein the step of determining contact resistance includes calculating a value of (V/I) from information measured the probe.

29. The product of claim 28, wherein the step of determining a number of monolayers for the interfacial oxide composition in relation to the determined contact resistance relation logic is performed using a look up table.

30. The product of claim 29, where when a measured the value of (V/I) is approximately less than or equal to 50 ohm cm, the wafer is determined to have less than one monolayer of in the interfacial oxide layer.

31. The product of claim 30, wherein the signal indicates a pass.

32. The product of claim 29, where when a measured the value of (V/I) is greater than approximately 1000 ohm cm, the wafer is determined to more than two monolayers in the interfacial oxide layer.

33. The method of claim 32, wherein the signal indicates a fail.

34. The product of claim 30, where when a measured the value of (V/I) is greater than approximately 50 ohm cm and less than approximately 1000 ohm cm, the wafer is determined to have at least one monolayer in the interfacial oxide layer.

35. The product of claim 30, wherein the step of measuring is performed following a deposition step.

36. The product of claim 35, wherein the step of measuring is performed in-line following precleaning and deposition, during a fabrication process.
